(19) United States
(12) Patent Application Publication
(10) Pub. No.: US 2026/0310355 A1
(43) Pub. Date: Oct. 8, 2026

(54) INFORMATION PROCESSING SYSTEM HAVING IMPROVED COMPUTATIONAL THROUGHPUT OF PROCESSING IN MEMORY BY MAXIMIZING MEMORY BANDWIDTH IN A MULTI-CHANNEL MEMORY THAT SUPPORTS A MEMORY BUS INTERFACE HAVING LIMITED BANDWIDTH

(71) Applicants: SK hynix Inc., Icheon-si (KR); KOREA UNIVERSITY RESEARCH AND BUSINESS FOUNDATION, Seoul (KR)

(72) Inventors: Seon Wook KIM, Seoul (KR); Seok Young KIM, Seoul (KR); Mun Seong PARK, Seoul (KR)

(21) Appl. No.: 19/238,005

(22) Filed: Jun. 13, 2025

(30) Foreign Application Priority Data
Apr. 7, 2025 (KR) 10-2025-0044771

(51) Int. Cl. G06F 3/06

(52) U.S. Cl. CPC G06F 3/0613; G06F 3/0659; G06F 3/0673

(57) ABSTRACT

An information processing system having a multi-channel memory structure achieves improved computational throughput of Processing In Memory (PIM) in multiple channels by using a channel level (CL) burst circuit. The information processing system includes the CL burst circuit configured to control a read or write operation between a channel arbiter and a memory controller, to generate a plurality of CL packets based on a memory packet including memory control information received from the channel arbiter and operand attribute (O/A) information stored in the CL burst circuit, and to transmit the plurality of CL packets to the plurality of memory controllers included in a plurality of channels, respectively.

### CROSS-REFERENCE TO RELATED APPLICATION

This application claims priority under 35 U.S.C. §119(a) to Korean Patent Application No. 10-2025-0044771, filed in the Korean Intellectual Property Office on Apr. 07, 2025, the entire contents of which are incorporated herein by reference.

### BACKGROUND

### 1. Technical Field

The present disclosure relates to an information processing system, and particularly, to an information processing system having improved computational throughput of processing-in memory (PIM) by maximizing a memory bandwidth by using a channel level (CL) burst circuit in a memory subsystem that is connected to a host through a limited memory bus interface and that supports multiple channels.

### 2. Related Art

A central processing unit (CPU) uses a low-capacity high-speed cache as on-chip memory. If data requested by the CPU are not present in the cache or the data of the cache needs to be evicted to off-chip memory, a cache controller requests the transmission and reception of the data from a high-capacity low-speed memory controller that may be located off-chip.

With the recent emergence of large-scale generative artificial intelligence (AI), a memory capacity that is required by an application is rapidly increasing. There is a memory bottleneck phenomenon (or a memory wall or a memory bandwidth shortage problem) in which a data transfer rate between a memory controller and Dynamic Random Access Memory(DRAM) limits the entire system performance due to the physical limits of a main board on which the CPU is mounted.

In order to solve the memory bandwidth shortage problem, a processing-in-memory (PIM) technology capable of reducing a movement of data between the CPU and the memory by adding a processing unit (PU) capable of processing within the memory some of computations that would otherwise be performed in the CPU is proposed and used.

In the following description, it is assumed and described that DRAM in which a PU is embedded is PIM.

In order to maximize the effect of using the PIM, the PIM may be disposed in each of multiple memory channels to secure parallelism of computations.

FIG. 1 illustrates an example of a conventional information processing system 100.

The conventional information processing system 100 includes a core unit 110 including cache memory, a multi-channel memory interface 120, and a multi-channel information processing device 130.

The multi-channel memory interface 120 may include a hand-shaking-based transaction protocol (e.g., Advanced eXtensible Interface (AXI), Advanced High-Performance Bus (AHB), or Advanced Peripheral Bus (APB) as defined in the Arm Advanced Microcontroller Bus Architecture (AMBA)) that performs read/write operations between a last-level cache included in the core unit 110 and memory controllers (MCs) that constitute the multi-channel information processing device 130, a decoder circuit (address/CMD decoder), and a channel arbiter that steers a transaction in accordance with a channel address.

The channel arbiter determines an entry queue that will issues a command that is input based on channel information of an address decoded by the decoder circuit (address/CMD decoder).

The multi-channel information processing device 130 includes a plurality of channels. Each of the plurality of channels includes DRAM in which an MC and a PU are embedded, that is, PIM. Each of the MCs may control PIM belonging to the same channel, and does not affect an operation of another channel.

The number of MCs is C (C is a natural number) corresponding to the number of channels. Each of the MCs MC0 to MCC-1 performs read/write operations on DRAM belonging to the same channel based on address/command/data information, among pieces of information that are decoded by the decoder circuit (address/CMD decoder) and applied via the channel arbiter, or enables the PU to perform computations by using such an operation.

An independent entry queue, scheduler, and DRAM PHY are present within the MC that is installed for each channel, and may execute a task that is assigned separately from another memory controller. The scheduler may perform a role of processing a memory request in an optimized way while complying with various timing restrictions of DRAM.

A request (i.e., a memory request) for a specific operation from the CPU is transmitted to the MC of a specific channel through the memory bus and the channel arbiter so that the MC performs only memory read/write on a corresponding channel or the PU performs an operation based on the request. If a very limited bandwidth of a memory bus is supported the AXI protocol, only one channel or a small number of channels, among multiple channels, are able to operate simultaneously. An environment in which multiple memory requests cannot be simultaneously processed in a memory system that supports multiple channels may greatly degrade a computational processing ability because the parallelism of the memory channels translates into the computation parallelism of PIM.

### SUMMARY

In an embodiment, an information processing system may include a channel level (CL) burst circuit configured to control a read or write operation between a channel arbiter and a memory controller, configured to generate a plurality of CL packets based on a memory packet including memory control information received from the channel arbiter and operand attribute (O/A) information stored in the CL burst circuit, and configured to transmit the plurality of CL packets to the plurality of memory controllers included in a plurality of channels, respectively. The memory controller performs a task by receiving a related CL packet, among the plurality of CL packets. A response packet of the CL packet except a start packet is invalidated by a memory interface and is not transmitted to a host.

### BRIEF DESCRIPTION OF THE DRAWINGS

FIG. 1 illustrates a conventional information processing system.

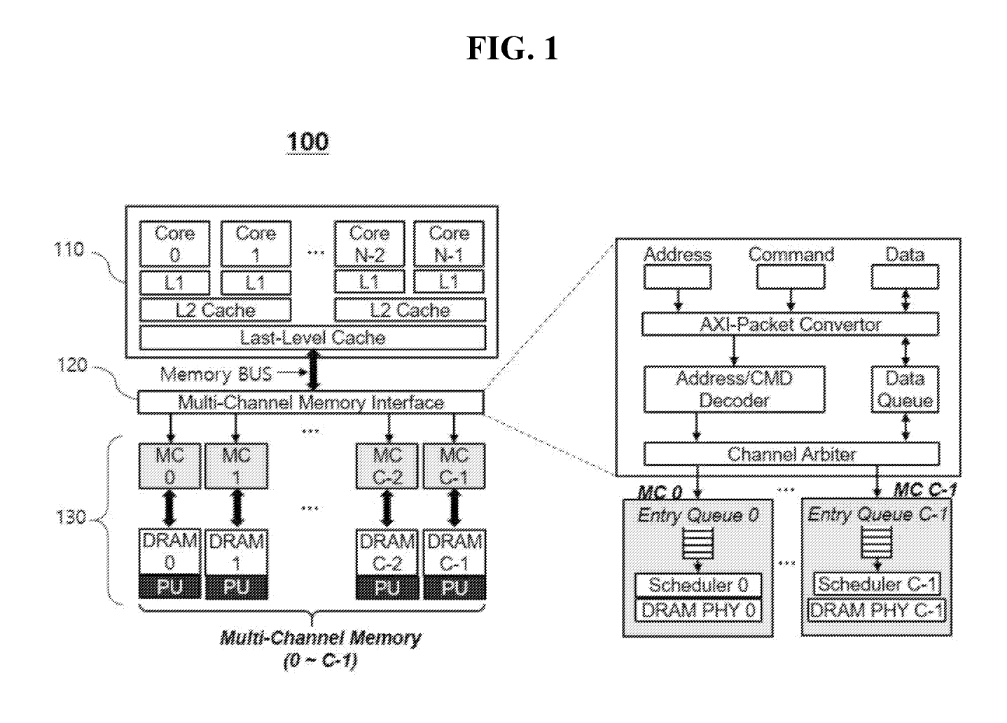

FIG. 2 illustrates an information processing system according to an embodiment of the present disclosure.

FIG. 3 is a block diagram of a channel level (CL) interface unit.

FIG. 4 illustrates a bit field of an operand attribute.

FIG. 5 is a block diagram of a CL packet generator.

FIG. 6 illustrates an operation of a conventional information processing system.

FIG. 7 illustrates an operation in a CL normal mode during an operation of the information processing system according to an embodiment of the present disclosure.

FIG. 8 illustrates an operation in a CL broadcast mode during an operation of the information processing system according to an embodiment of the present disclosure.

FIGS. 9A and 9B illustrate an example in which an operation of a 4x4 matrix for each element is performed by using a CL burst circuit according to an embodiment of the present disclosure.

### DETAILED DESCRIPTION

Embodiments of the present disclosure provide an information processing system having improved computational throughput of processing-in memory (PIM) by maximizing a memory bandwidth by using a channel level (CL) burst circuit in a memory subsystem that is connected to a host through a limited memory bus interface and that supports multiple channels.

Technical objects to be achieved by the present disclosure are not limited to the aforementioned object, and the other objects not described above may be evidently understood from the following description by a person having ordinary knowledge in the art to which the present disclosure pertains.

The information processing system having improved use efficiency of PIM for each channel according to an embodiment of the present disclosure has an advantage in that it can improve computational throughput of PIM by maximizing a memory bandwidth by increasing the access granularity of DRAM based on a characteristic (channel-level parallelism (CLP)) in which computations can be independently performed in a processing unit (PU) in which multi-channel memory constitutes PIM by performing read/write operations.

The improvement of the computational throughput of PIM by the information processing system is merely one application example and is not limited to PIM, and may be applied to all of fields for maximizing a memory bandwidth in a memory system that is connected to a host through a limited memory bus.

In order to sufficiently understand the present disclosure, operational advantages of the present disclosure, and an object achieved by carrying out the present disclosure, reference may be made to the accompanying drawings illustrating embodiments of the present disclosure and contents described with reference to the accompanying drawings.

Hereinafter, embodiments of the present disclosure are described in detail with reference to the accompanying drawings. The same reference numerals presented in the drawings refer to the same elements.

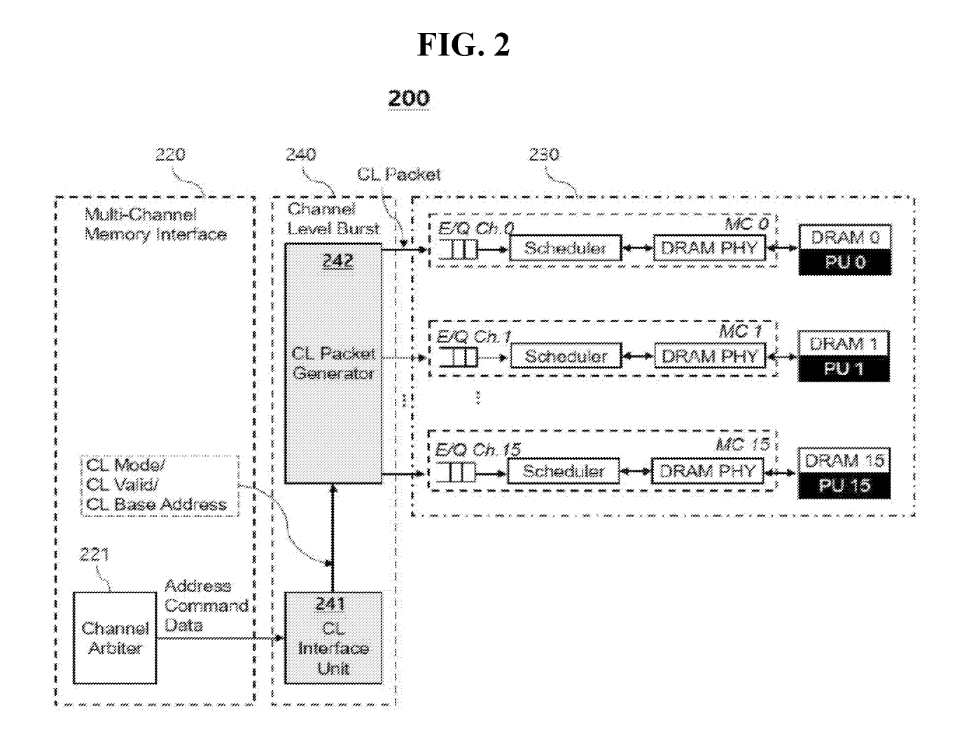

FIG. 2 illustrates an example of an information processing system 200 according to an embodiment of the present disclosure.

The information processing system 200 having improved computational throughput of a PIM by maximizing a memory bandwidth in a multi-channel memory subsystem that supports a memory bus interface having a limited bandwidth (hereinafter referred to as an “information processing system”) according to an embodiment of the present disclosure includes a multi-channel memory interface 220, a multi-channel information processing device 230, and a channel level (CL) burst circuit 240.

A channel arbiter 221 included in the multi-channel memory interface 220 performs read/write operations between a last-level cache included in cache memory (not illustrated) and memory controllers (MCs) included in the multi-channel information processing device 230.

The CL burst circuit 240 includes a CL interface unit 241 that generates a CL burst control signal (CL Mode, CL Valid, CL Base Address) based on memory control information (Address, Command, Data) received from the channel arbiter 221 and operand attribute information stored in the CL burst circuit 240, and a CL packet generator 242 that generates a CL packet per channel based on the CL burst control signal (CL Mode, CL Valid, CL Base Address) and that transmits the CL packet to the MCs included in the multi-channel information processing device 230.

The multi-channel information processing device 230 includes a plurality of channels Ch.0 to Ch.15. The plurality of channels Ch.0 to Ch.15 includes MCs MC 0 to MC 15, respectively, and pieces of DRAM in which processing units (PUs) PU0 to PU15 are embedded, that is, pieces of processing-in-memory (PIM), respectively. Each of the MCs MC 0 to MC 15 may control PIM belonging to the same channel, and does not affect an operation of another channel. The MC installed in each channel includes an independent entry queue (E/Q), scheduler, and DRAM PHY for each corresponding channel, and may execute a task that is assigned thereto separately from another memory controller. The scheduler performs a role of processing a memory request in an optimized way while complying with various timing restrictions of corresponding DRAM.

In FIG. 2, the CL burst circuit 240 has been illustrated as being an independent device that is separated from the multi-channel memory interface 220 and the multi-channel information processing device 230. An embodiment in which the CL burst circuit 240 is included in any one of the multi-channel memory interface 220 and the multi-channel information processing device 230 is possible.

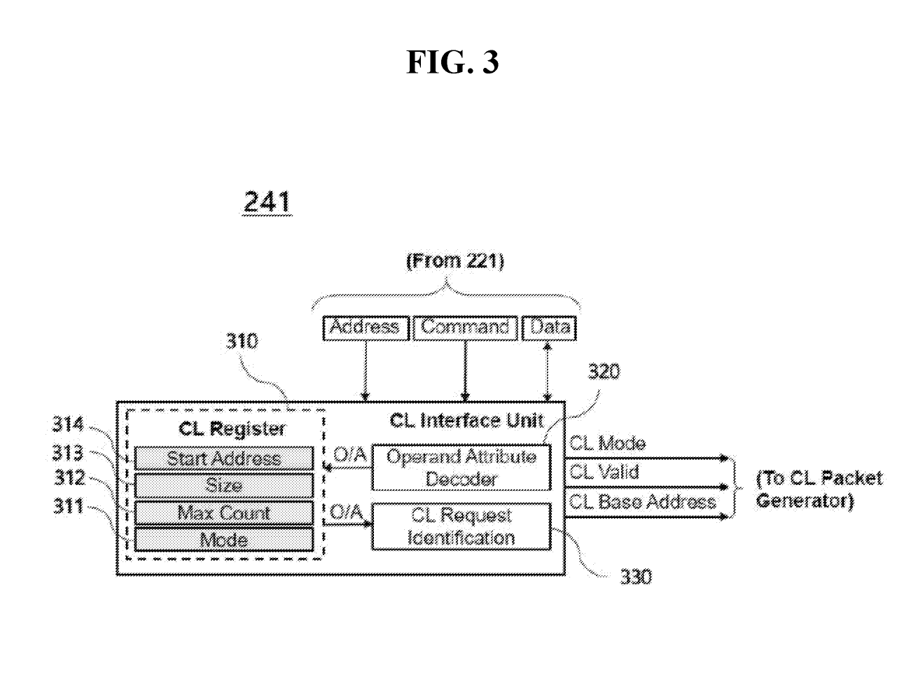

FIG. 3 is a block diagram of the CL interface unit 241.

Referring to FIG. 3, the CL interface unit 241 includes a CL register 310, an operand attribute (O/A) decoder 320, and a CL request identification device 330.

The O/A decoder 320 receives/decodes O/A information intended for an MC and transmits the O/A information to the CL register 310. In this case, the O/A information having a form of a memory packet is transmitted from the CPU to the MC. The CL register 310 stores the O/A information decoded by the O/A decoder 320. The stored O/A information includes a start address (Start Address), a CL size (Size), a CL maximum count value (Max Count), and a mode value (Mode). The OA information stored in the CL register 310 needs to be stored before a PIM computation is performed by a programmer.

The CL request identification device 330 identifies a start packet, based on O/A information stored in the CL register 310 and memory control information (Address, Command, Data) transmitted by the channel arbiter 221, identifies the start and end of a CL burst operation, and generates the CL burst control signal (CL Mode, CL Valid, CL Base Address).

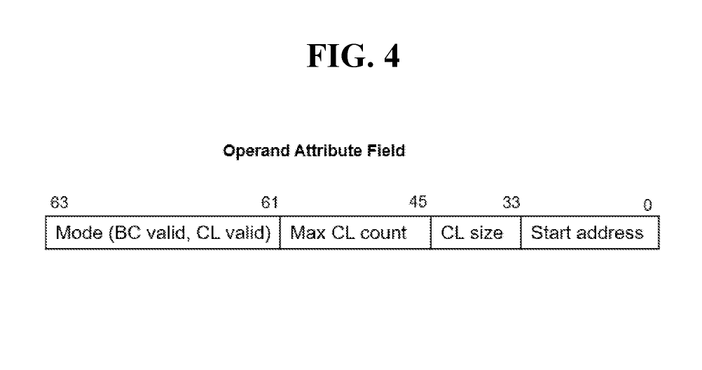

FIG. 4 illustrates an example of the bit field of an operand attribute (O/A).

Referring to FIG. 4, assuming that the bit field of the O/A (Operand Attribute field) includes a total of 64 bits, the O/A includes the start address (Start Address) of 33 (0 to 32) bits, the CL size (Size) of 12 bits (33 to 44), the CL maximum count value (Max Count) of 16 bits (45 to 60), and the mode value (Mode) of 3 bits (61 to 63).

The start address is the start address of a start packet, and includes a channel that is a target, a memory bank, and an identifier of a column and row. A CL burst function may be performed in response to the start address being present in a memory request.

The CL size indicates the number of CL packets to be generated by a CL burst operation.

In a PIM system, the channel level (CL) maximum count defines how many times a burst operation can be repeated consecutively on a memory channel. It is represented by the CL maximum count value, which specifies the repetition count of a CL burst operation. This mechanism helps manage memory bandwidth efficiently and avoids monopolization of a single channel.

The mode value includes CL normal mode activation information (CL Valid) and CL broadcast mode activation information (BC Valid) that are included in a CL burst operation.

Referring to FIG. 3, the CL burst control signal (CL Mode, CL Valid, CL Base Address) that is output by the CL request identification device 330 includes a CL mode control signal (CL Mode), a CL activation signal (CL Valid), and a CL base address.

The CL mode control signal enables one of the CL normal mode and the CL broadcast mode to be selected. The information processing system 200 according to an embodiment of the present disclosure may operate by selecting one of two operation modes, that is, the CL normal mode and the CL broadcast mode, which is described later.

The CL activation signal includes information on a channel that is activated. For example, when the CL activation signal CL Valid[0] is activated, a 0-th CL packet (Ch.0 CL Packet) may be transmitted to a 0-th channel (Ch.0). When the CL activation signal CL Valid is activated, a fifteenth CL packet (Ch.15 CL Packet) may be transmitted to a fifteenth channel (Ch.15). As will be described later, in the CL normal mode, only one CL activation signal corresponding to a start packet is activated during a period in which the start packet is processed. In the CL broadcast mode, all of CL activation signals are activated during a period in which a start packet is processed.

In this case, the CL packet refers to a packet that is generated for each channel by the CL packet generator 242, and is described later.

The CL base address corresponds to the start address, that is, the first portion (bits 0…32) of the O/A field illustrated in FIG. 4.

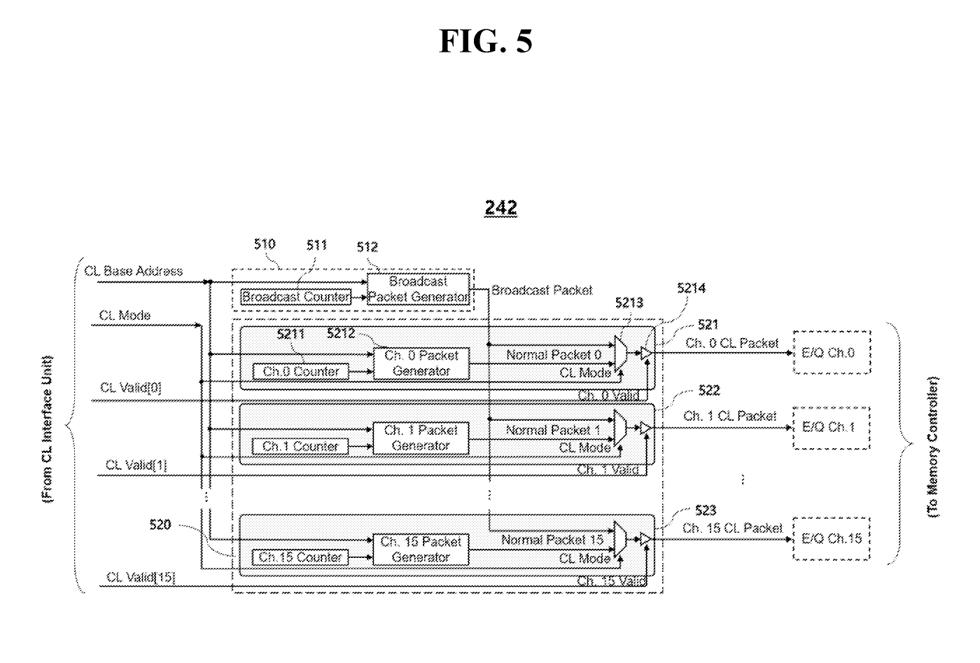

FIG. 5 is a block diagram of the CL packet generator 242.

The CL packet generator 242 includes a broadcast processing unit 510 and a normal processing unit 520.

The broadcast processing unit 510 generates a broadcast packet in response to the CL base address, and includes a broadcast counter 511 and a broadcast packet generator 512.

The broadcast packet generator 512 generates a broadcast packet in response to a count signal output by the broadcast counter 511 and the CL base address. The count signal output by the broadcast counter 511 is used to determine timing at which the broadcast packet generator 512 generates the broadcast packet.

The normal processing unit 520 includes unit channel processing units 521, 522 to 523 each of which selects and outputs one of a normal packet that is generated within that unit channel processing unit and a broadcast packet that is generated by the broadcast processing unit 510, in response to the CL activation signal (CL Valid) and the channel level mode signal (CL Mode) for each channel.

A 0-th unit channel processing unit 521 generates a 0-th CL packet (Ch.0 CL Packet), among CL packets, based on a 0-th (zeroth) CL activation signal (CL Valid[0]), among the CL base address, the CL mode control signal (CL Mode), and the CL activation signal (CL Valid), and a broadcast packet, and includes a Ch.0 counter 5211, a Ch.0 packet generator 5212, a Ch.0 multiplexer (MUX) 5213, and a Ch.0 buffer 5214.

The Ch.0 packet generator 5212 generates a Ch.0 normal packet (Normal Packet 0) in response to a count signal output by the Ch.0 counter 5211 and the CL base address. The count signal of the Ch.0 counter 5211 is used to determine timing at which the Ch.0 packet generator 5212 needs to generate the Ch.0 normal packet (Normal Packet 0).

The Ch.0 MUX 5213 selects and outputs one of the Ch.0 normal packet (Normal Packet 0) and a broadcast packet in response to the CL mode control signal (CL Mode).

The Ch.0 buffer 5214 outputs a 0-th CL packet (Ch.0 CL Packet) by buffering a signal output by the Ch.0 MUX 5213 in response to the 0-th CL activation signal (CL Valid[0]). The Ch.0 buffer 5214 may be implemented with a tri-state buffer in which the 0-th CL packet (Ch.0 CL Packet) is output to its output terminal or the state of the output terminal becomes a high impedance state in response to a 0-th channel activation signal (CL Valid[0]).

The first unit channel processing unit 522 generates a first CL packet (Ch.1 CL Packet), among the CL packets, based on a first CL activation signal (CL Valid[1]), among the CL base address, the CL mode control signal (CL Mode), and the CL activation signal (CL Valid), and a broadcast packet. Although reference numeral has not been described in FIG. 5, a first unit channel processing unit 522 is the same as the 0-th unit channel processing unit 521 in that the first unit channel processing unit 522 includes a Ch.1 counter, a Ch.1 packet generator, a Ch.1 MUX, and a Ch.1 buffer. The functions of the Ch.1 counter, Ch.1 packet generator, Ch.1 MUX, and Ch.1 buffer of the first unit channel processing unit 522 are the same as those of the 0-th unit channel processing unit 521.

A fifteenth unit channel processing unit 523 generates a fifteenth CL packet (Ch.15 CL Packet), among the CL packets, based on a fifteenth CL activation signal (CL Valid, among the CL base address, the CL mode control signal (CL Mode), and the CL activation signal (CL Valid), and a broadcast packet. Although reference numeral has not been described in FIG. 5, the fifteenth unit channel processing unit 521 is the same as the 0-th unit channel processing unit 521 in that the fifteenth unit channel processing unit 521 includes a Ch.15 counter, a Ch.15 packet generator, a packet generator, a Ch.15 MUX, and a Ch.15 buffer. The functions of the Ch.15 counter, Ch.15 packet generator, packet generator, Ch.15 MUX, and Ch.15 buffer of the fifteenth unit channel processing unit 521 are the same as those of the 0-th unit channel processing unit 521.

Each of the 0-th CL packet (Ch.0 CL Packet) and the first CL packet (Ch.1 CL Packet) to the fifteenth CL packet (Ch.15 CL Packet) is transmitted to each corresponding MC (not illustrated).

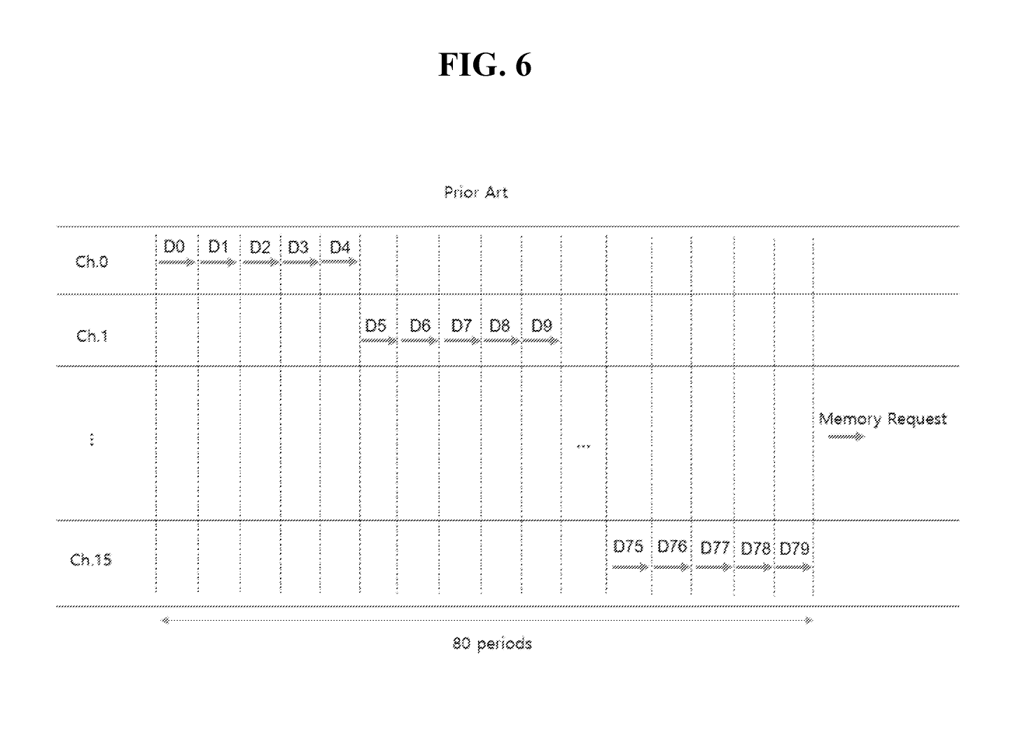

FIG. 6 is a diagram describing an operation of a conventional information processing system.

Hereinafter, it is assumed that the information processing system includes 16 channels and each of the 16 channels executes five tasks, for convenience of description. In FIG. 6, a dotted or solid line arrow indicates a packet including a memory request, D indicates data included in a corresponding packet, and an Arabic number written on the right of D indicates an address offset between the first memory request (0) packet and a subsequent memory request packet.

Furthermore, it is assumed that a period between two dotted vertical lines that are adjacent to each other is one signal processing period, for convenience of description.

Referring to FIG. 6, in the prior art, when the CPU transmits memory requests for the 0-th channel Ch.0, only the PIM (not illustrated) belonging to the 0-th channel Ch.0 executes the requested task and transmits the results of the execution to the CPU. It may be seen that the PIM within the remaining channels (Ch.1 to Ch.15) does not execute any task until the execution (D0 to D4) of a total of 5 memory requests is consecutively completed in the 0-th channel Ch.0.

Accordingly, it may be seen that 80 signal processing periods (80 Periods) are used to execute 80 tasks 0 to 79 assigned to the channels Ch.0 to Ch.15. The reason for this is that the conventional information processing system is designed so that the PIM included in another channel does not operate when the PIM included in one channel operates although the PIM included in each channel individually receives indication and executes a task.

The normal processing unit 520 according to an embodiment of the present disclosure includes the 0-th, first to fifteenth unit channel processing units 521, 522 to 523 each of which selects and outputs one of a normal packet generated within each unit channel processing unit and a broadcast packet generated by the broadcast processing unit 510, in response to the CL activation signal (CL Valid) and the channel level mode signal (Mode) for each channel. That is, the information processing system according to an embodiment of the present disclosure has been invented to operate in the CL normal mode and the CL broadcast mode.

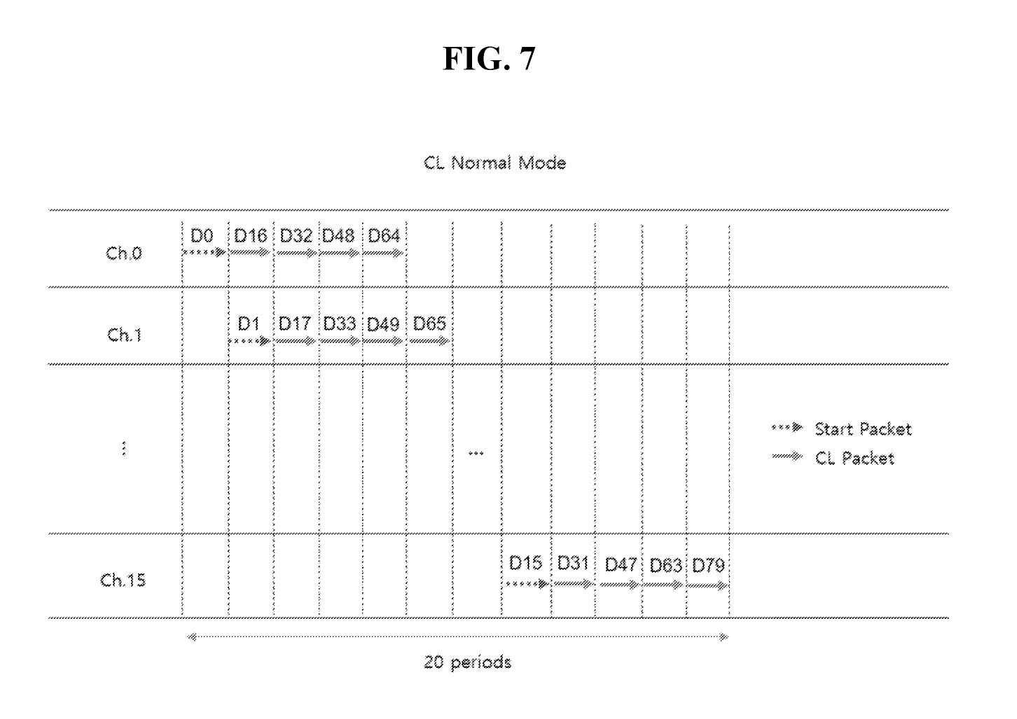

FIG. 7 is a diagram describing an operation in the CL normal mode during an operation of the information processing system according to an embodiment of the present disclosure.

The operation of FIG. 7 is portrayed in the same manner as that of the prior art shown in FIG. 6 except that a memory request indicated by a dotted line includes the address of a start packet and only a channel in which a memory request indicated by a dotted line is illustrated responds to the CPU.

Hereinafter, it is assumed that the CL size is 4, for convenience of description.

Referring to FIG. 7, assuming that in the CL normal mode, the CPU transmits a memory request in order of the first channel Ch.0 to the fifteenth channel Ch.15 starting from the first channel Ch.0, during the first period, the memory controller MC0 belonging to the 0-th channel Ch.0 receives and processes a start packet, and transmits a response to the results of the processing to the CPU. In this case, the PIM belonging to the 0-th channel Ch.0 performs computation by using data that are input to and output from the DRAM in a process of processing a corresponding packet.

During the second period, the memory controller MC1 belonging to the first channel Ch.1 processes a start packet indicated by a dotted line. The PIM belonging to the first channel Ch.1 performs computation by using data that are input to and output from the DRAM in a process of processing a corresponding packet. At this time, the memory controller of each of other channels Ch.2 to Ch.15 does not receive a memory packet. However, the memory controller MC0 belonging to the 0-th channel Ch.0 receives the 0-th CL packet (Ch.0 CL Packet) generated based on an address that is included in a start packet received during a previous period, and executes a task D16 on the 0-th CL packet. During the second period, the PIM belonging to the 0-th channel Ch.0 executes a task in accordance with the 0-th CL packet (Ch.0 CL Packet), but a response to the 0-th CL packet is invalidated by the memory interface and is not transmitted to the CPU.

Subsequently, during the sixteenth period, the memory controller belonging to the sixteenth channel Ch.15 processes a start packet indicated by a dotted line. The PIM belonging to the fifteenth channel Ch.15 performs computation by using data that are input to and output from the DRAM in a process of processing a corresponding packet. During this period, each of the memory controller MC0 belonging to the 0-th channel Ch.0 to the memory controller MC14 belonging to the fourteenth channel (Ch.14) (not illustrated) may process a CL packet generated based on an address included in a start packet that is received during a previous period, and the PIM of each channel performs computation. However, a response such as a response D30 that may be generated by the fourteenth channel (Ch.14) (not illustrated) for the processing results is invalidated by the memory interface and is not transmitted to the CPU.

The PIM of the 0-th channel Ch.0 terminates all of the tasks during the fifth signal processing period because the CL size is 4. During the sixth signal processing period, the state of the PIM becomes an idle state unless new indication is present. Likewise, the PIM of the first channel Ch.1 terminates all of the tasks during the sixth signal processing period. During the seventh signal processing period, the state of the PIM becomes an idle state unless new indication is present.

In other words, in the CL normal mode, during a specific period, a specific channel executes a task included in a start packet according to the start packet, and transmits the results of the execution to the CPU. During each subsequent period, each channel generates a CL memory request (CL Packet) by using an address included in a start packet that is received during a previous period in the state in which a memory request has not been received from the CPU.

That is, assuming that start packets are sequentially applied to the 16 channels, only the 0-th channel is activated during the first period, the 0-th and first channels are activated during the second period, the 0-th, first, and second channels are activated during the third period, and all of the 0-th to fifteenth channels may be activated during the sixteenth period.

As described above, during a specific period to which a start packet is applied, only a corresponding channel transmits and receives data to and from the CPU, but the PIM of another channel can execute a task during the specific period. Accordingly, the idle period in an operation of the PIM can be minimized.

However, only a channel having a start packet indicated by a dotted line, that is, a memory request, transmits processing results to the CPU. During a period in which a CL packet indicated by a solid line is performed, PIM computation is performed under the control of the MC of a corresponding channel, but the results of the computation are not transmitted to the CPU.

Each of the memory controllers MC0 to MC C-1 that constitute the information processing system 200 according to an embodiment of the present disclosure executes a task by receiving a corresponding CL packet, among a plurality of CL packets, but a response packet of the CL packet except a start packet may be invalidated by the memory interface and might not be transmitted to a host.

Assuming that a task having the same size as that of the conventional information processing system illustrated in FIG. 6 is executed, it may be seen that fast processing is possible compared to a conventional information processing system in that the task can be completed during a total of 20 signal processing periods (20 Periods).

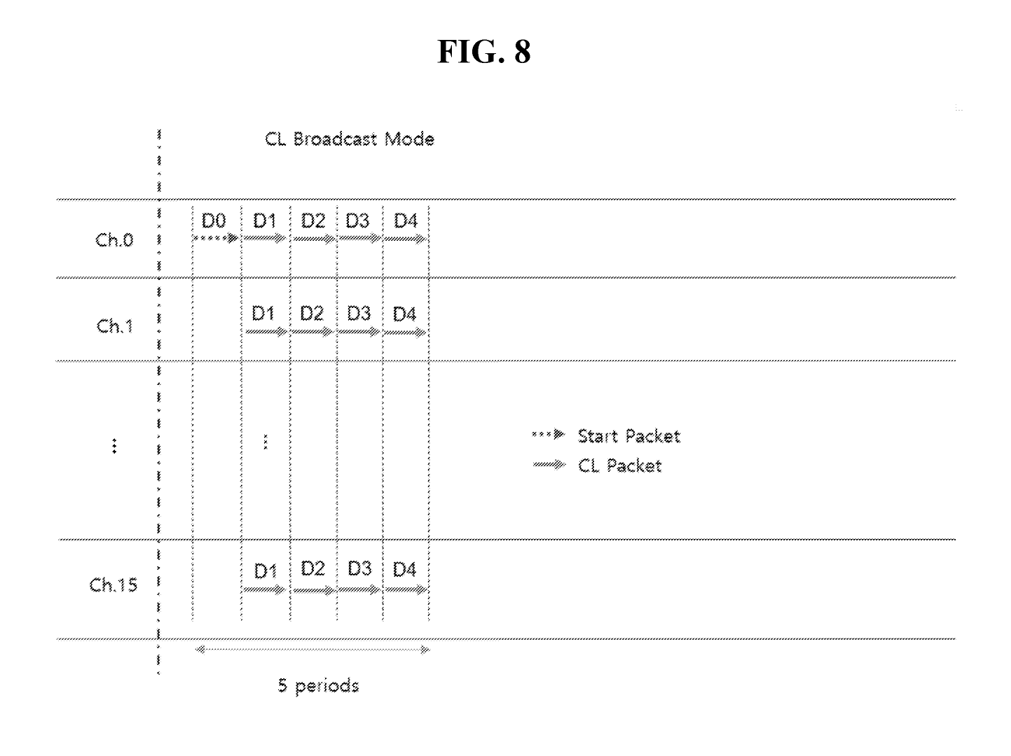

FIG. 8 is a diagram describing an operation in the CL broadcast mode during an operation of the information processing system according to an embodiment of the present disclosure.

The operation of FIG. 8 is the same as that of the prior art in that a memory request indicated by a dotted line in FIG. 8 includes the address of a start packet and only a channel in which the memory request indicated by the dotted line has been illustrated responds to the CPU.

Referring to FIG. 8, in the CL broadcast mode, during the first period, the 0 channel Ch.0 executes a task according to the start packet. In this case, during the same period, the broadcast packet generator 512 generates the CL packets (Ch.1 CL Packet to Ch.15 CL Packet) each corresponding to each channel based on an address included in a start packet, and transmits each of the generated CL packets (Ch.1 CL Packet to Ch.15 CL Packet) to the remaining channels Ch.1 to Ch.15 so that each channel executes a task by using the generated CL packet. Accordingly, each of all of the channels Ch.0 to Ch.15 executes a task corresponding to the 0-th CL packet (Ch.0 CL Packet).

From a subsequent period, the same operation as that during the first period is repeated as the broadcast packet generator 512 generates a CL packet having the CL size based on a count signal output by the broadcast counter (not illustrated) and transmits the CL packet to a corresponding channel.

It will be effective if each of a plurality of channels selects and uses the CL broadcast mode according to an embodiment of the present disclosure when each channel has to perform the same operation.

In other words, when the information processing system 200 according to an embodiment of the present disclosure operates in the CL broadcast mode, the CL burst circuit 240 executes a task according to a start packet in a plurality of channels and transmits the results of the execution of the task to a related MC during one signal processing period, and generates a CL packet based on an address included in the start packet in the state in which the plurality of channels has not received a memory request from the CPU during a subsequent signal processing period.

From FIG. 8, it may be seen that assuming that the information processing system 200 according to an embodiment of the present disclosure executes a task having the same size as that of the conventional information processing system illustrated in FIG. 6, the information processing system 200 can perform fast processing compared to the conventional information processing system in that a task can be completed during a total of 5 signal processing periods (5 Periods).

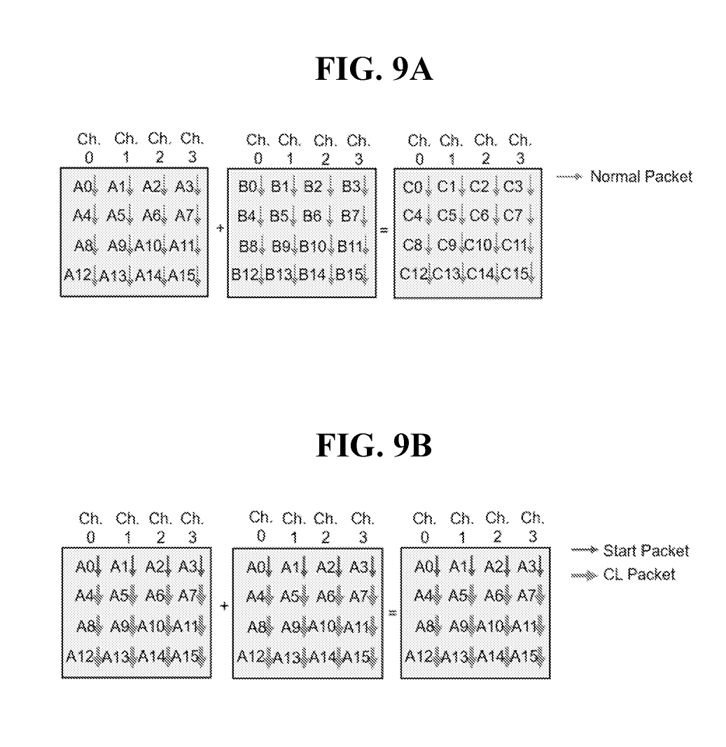

FIG. 9A and 9B are a diagram describing an example in which an operation of a 4x4 matrix for each element is performed by using the CL burst circuit according to an embodiment of the present disclosure.

It is assumed that the results of the addition of a matrix A and a matrix B are stored in a matrix C, for convenience of description.

In FIG. 9A and 9B, three 4×4 matrix operands A, B, and C are stored in the four channels Ch.0 to Ch.3. A0 to A15, B0 to B15, and C0 to C15 each indicate memory requests for reading or writing an element of each matrix.

FIG. 9A illustrates an example of an element-wise operation of the conventional information processing system 100. An arrow indicates a memory request (Normal Packet) for reading or writing an element that is transmitted by the CPU. It may be seen that 16 memory requests per operand are required. That is, in order to read operands A and B, the CPU needs to generate 16×2 memory requests. In order to store the results of an operation in an operand C, the CPU also needs to generate the 16 memory requests.

FIG. 9B illustrates an example of an element-wise operation of the information processing system 200 including the CL burst circuit 240 according to an embodiment of the present disclosure. An arrow indicates a start packet and a CL packet after the CL burst function according to an embodiment of the present disclosure is applied. In the case of FIG. 7B, start addresses A0, B0, and C0 will be stored in the operand attribute, 3 will be stored in the CL size, 1 will be stored in the CL maximum count value (Max Count), and the CL normal mode will be stored in the mode value (Mode).

In FIG. 9B, when four memory requests A0 to A3 related to the operand A are transmitted to the CL burst circuit 240, the CL burst circuit 240 automatically generates the remaining packets A4 to A15 of the operand A based on information of the four memory requests A0 to A3. Each of the operands B and C also performs a task in the same manner as the operand A.

In the case of the conventional information processing system 100 illustrated in FIG. 9A, the 16×2 memory requests are required because a memory request is required for each element of the 4×4 matrix.

In contrast, in the information processing system 200 illustrated in FIG. 9B according to an embodiment of the present disclosure, it may be seen that only a total of 4×3 memory requests are required because memory requests (start Packets) are required for only first four elements, among the elements of the 4×4 matrix, the CL burst circuit can automatically generate the remaining 12 elements, and memory requests corresponding to the remaining 12 elements are not required.

The technical spirit of the present disclosure has been described along with the accompanying drawings, but this exemplarily describes preferred embodiments of the present disclosure and is not intended to limit the present disclosure. Furthermore, it is evident that any person having ordinary knowledge in the field to which the present disclosure pertains may modify and imitate the present disclosure without departing from the category of the technical spirit of the present disclosure.

What is claimed is:

1. An information processing system comprising:
a channel level (CL) burst circuit configured to:
control a read or write operation between a channel arbiter and a memory controller,
generate a plurality of CL packets based on a memory packet comprising memory control information received from the channel arbiter and operand attribute (O/A) information stored in the CL burst circuit, and
transmit the plurality of CL packets to the plurality of memory controllers included in a plurality of channels, respectively,
wherein the memory controller performs a task in response to receiving a related CL packet, among the plurality of CL packets, and
a response packet of a CL packet that is not a start packet is invalidated by a memory interface and is not transmitted to a host.

2. The information processing system of claim 1, wherein the O/A information comprises:
a start address that is a start address of the start packet and comprising a channel that is a target, a memory bank, an identifier of a column and a row;
a CL size indicative of a number of the CL packets to be generated by a CL burst operation;
a CL maximum count value indicative of a number of repetitions of the CL burst operation; and
a mode value comprising CL normal mode and CL broadcast mode activation information that are included in the CL burst operation.

3. The information processing system of claim 2, wherein the CL burst circuit comprises:
a CL interface unit configured to generate a CL burst control signal, based on a memory request, the memory packet comprising the memory control information and the O/A information; and
a CL packet generator configured to generate the CL packet per channel based on the CL burst control signal.

4. The information processing system of claim 3, wherein the CL interface unit comprises:
a CL register configured to store the O/A information;
an O/A decoder configured to receive and decode a memory packet comprising the O/A information from the memory controller and to transmit the memory packet to the CL register; and
a CL request identification device configured to identify the start packet included in the memory request based on the O/A information stored in the CL register and the memory control information transmitted by the channel arbiter, to identify a start and end of the CL burst operation, and to generate the CL burst control signal.

5. The information processing system of claim 3, wherein the CL burst control signal comprises:
a CL mode control signal that enables one of the CL normal mode and the CL broadcast mode to be selected;
a CL activation signal comprising information on an activated channel; and
a CL base address corresponding to the start address.

6. The information processing system of claim 5, wherein the CL packet generator comprises:
a broadcast processing unit configured to generate a broadcast packet in response to the CL base address; and
a normal processing unit comprising a plurality of unit channel processing units each configured to output the CL packet by selecting one of a normal packet generated in response to the CL activation signal and the CL mode control signal and a broadcast packet generated by the broadcast processing unit for each channel.

7. The information processing system of claim 6, wherein the broadcast processing unit comprises:
a broadcast counter; and
a broadcast packet generator configured to generate the broadcast packet in response to a count signal output by the broadcast counter and the CL base address.

8. The information processing system of claim 7, wherein the count signal output by the broadcast counter is used to determine timing at which the broadcast packet generator generates the broadcast packet.

9. The information processing system of claim 6, wherein the normal processing unit comprises a plurality of unit channel processing units, including:
a 0-th unit channel processing unit configured to generate a 0-th CL packet, among the plurality of CL packets, based on the CL base address, the CL mode control signal, a 0-th CL activation signal included in the CL activation signal, and the broadcast packet; and
a first unit channel processing unit configured to generate a first CL packet, among the plurality of CL packets, based on the CL base address, the CL mode control signal, a first CL activation signal included in the CL activation signal, and the broadcast packet.

10. The information processing system of claim 9, wherein each of the plurality of unit channel processing units comprises:
a channel counter;
a channel packet generator configured to generate a channel normal packet in response to the count signal output by the channel counter and the CL base address;
a channel multiplexer (MUX) configured to select and output one of the channel normal packet and the broadcast packet in response to the CL mode control signal; and
a channel buffer configured to output the a CL packet to the respective channel of that unit channel processing unit by buffering a signal output by the channel MUX in response to the CL activation signal corresponding to that unit channel processing unit.

11. The information processing system of claim 10, wherein in each of the plurality of unit channel processing units the channel buffer is a tri-state buffer in which the CL packet is output through its output terminal in response to a channel activation signal and the output terminal can enter a high impedance state.

12. The information processing system of claim 10, wherein in each of the plurality of unit channel processing units the count signal of the channel counter is used to determine timing at which the channel packet generator needs to generate the channel normal packet.

13. The information processing system of claim 2, wherein when the information processing system operates in the CL normal mode, the CL burst circuit:
executes a task included in the start packet in an arbitrary one channel and transmits the results of the execution of the task to a related memory controller, during one signal processing period, and
generates a CL packet based on an address included in the start packet that is received during a previous signal processing period in a state in which each channel has not received a memory request from a central processing unit (CPU), during each subsequent signal processing period.

14. The information processing system of claim 2, wherein when the information processing system operates in the CL broadcast mode, the CL burst circuit:
performs a task according to the start packet in the plurality of channels and transmits the results of the execution of the task to a related memory controller, during one signal processing period, and
generates a CL packet based on an address included in the start packet in a state in which the plurality of channels has not received a memory request from a central processing unit (CPU), during a subsequent signal processing period.
